(19) United States
(12) Patent Application Publication
(10) Pub. No.: US 2018/0278022 A1
(43) Pub. Date: Sep. 27, 2018

(54) SURFACE-EMITTING SEMICONDUCTOR LASER

(71) Applicant: SUMITOMO ELECTRIC INDUSTRIES, LTD., Osaka (JP)

(72) Inventors: Nein-Yi LI, Albuquerque, NM (US); LI WANG, Albuquerque, NM (US); Yutaka ONISHI, Yamato-shi (JP)

(73) Assignee: SUMITOMO ELECTRIC INDUSTRIES, LTD., Osaka (JP)

(21) Appl. No.: 15/467,594

(22) Filed: Mar. 23, 2017

(51) Int. Cl. H01S 5/183; H01S 5/22

(52) U.S. Cl. CPC H01S 5/183; H01S 5/2214

(57) ABSTRACT

A surface-emitting semiconductor laser includes a stacked semiconductor layer on a substrate; and a post including a current constriction structure including an oxide portion and a semiconductor portion, and an active layer. The post includes a peripheral portion and first to fourth portions. The oxide portion is located in the second and fourth portions, and the semiconductor portion is located in the first and third portions. The post includes first to fourth level parts that are sequentially arranged in a direction from the substrate to the stacked semiconductor layer. The active layer and the current constriction structure are located in the first and second level parts, respectively. The peripheral portion includes a first region having a first hydrogen concentration. The second level part includes a second region having a second hydrogen concentration. The first and second hydrogen concentrations are larger than that of the first portion.

### BACKGROUND OF THE INVENTION

### 1. Field of the Invention

The present invention relates to surface-emitting semiconductor lasers.

### 2. Description of the Related Art

Non-Patent Literature 1, A. Haglund et al., “Single Fundamental Mode Output Power Exceeding 6 mW from VCSELs with a Shallow Surface Relief,” IEEE Photonics Technology Letters, vol. 16, no. 2, pp. 368-370, 2004”, discloses vertical cavity surface-emitting lasers (VCSELs).

### SUMMARY OF THE INVENTION

For the operation of a surface-emitting semiconductor laser (vertical cavity surface-emitting semiconductor laser), a control of the optical modes, namely, the fundamental mode and the higher order mode is important. This optical-mode control is associated with the current distribution in a post of a surface-emitting semiconductor laser. However, a process for controlling the current distribution in the post is not known.

A surface-emitting semiconductor laser according to an aspect of the present invention includes a substrate having a principal surface; a stacked semiconductor layer disposed on the principal surface of the substrate; and a post having an upper surface and a side surface extending in a first direction from the substrate to the stacked semiconductor layer, the post including an upper semiconductor part, a current constriction structure, and a lower semiconductor part having an active layer, the current constriction structure including an oxide portion extending along the side surface of the post, and a semiconductor portion surrounded by the oxide portion. The stacked semiconductor layer is interposed between the substrate and the post. The post includes a peripheral portion extending in the first direction along the side surface of the post, a first portion away from the side surface of the post, the first portion extending in the first direction, a second portion extending in the first direction along the peripheral portion of the post, a third portion disposed between the first portion and the second portion, the third portion extending in the first direction along the first portion, and a fourth portion disposed between the second portion and the third portion, the fourth portion extending in the first direction along the second portion. The oxide portion is located in the second portion and the fourth portion of the post. The semiconductor portion is located in the first portion and the third portion of the post. The post includes a first level part, a second level part, a third level part, and a fourth level part that are sequentially arranged in the first direction. The active layer is located in the first level part, and the current constriction structure is located in the second level part. The peripheral portion includes a first region having a first hydrogen concentration. The first region spans the second level part, the third level part, and the fourth level part. The second level part includes a second region having a second hydrogen concentration. The first hydrogen concentration and the second hydrogen concentration are larger than a hydrogen concentration of the first portion. In addition, the second region has a thickness larger than a thickness of the oxide portion of the current constriction structure.

The above-described object and other objects, features, and advantages of the present invention will become more readily apparent from the following detailed description of the preferred embodiments of the present invention with reference to the accompanying drawings.

### BRIEF DESCRIPTION OF THE DRAWINGS

FIGS. 1A to 1D are schematic diagrams illustrating a surface-emitting semiconductor laser according to an embodiment.

FIG. 2 is a diagram illustrating the structures of regions with high resistivity in the surface-emitting semiconductor laser depicted in FIG. 1.

FIG. 3 is a diagram illustrating the structures of regions with high resistivity in the surface-emitting semiconductor laser depicted in FIG. 1.

FIG. 4 is a diagram illustrating the structures of regions with high resistivity in the surface-emitting semiconductor laser depicted in FIG. 1.

FIG. 5 is a diagram illustrating the structures of regions with high resistivity in the surface-emitting semiconductor laser depicted in FIG. 1.

FIG. 6 is a schematic diagram illustrating a surface-emitting semiconductor laser C having a region with high resistivity in a peripheral portion.

FIG. 7A is a graph showing the calculated values of the current distribution in the device structures of the first embodiment and Experimental Example, and FIGS. 7B and 7C are views showing the measured results of light emission patterns for the device structures of the first embodiment and Experimental Example.

FIGS. 8A to 8D are graphs showing the calculated values of the current distribution in the device structures according to the first, second, third and fourth embodiments.

### DESCRIPTION OF THE PREFERRED EMBODIMENTS

Some embodiments will be described below.

A surface-emitting semiconductor laser according to an embodiment includes (a) a substrate having a principal surface; (b) a stacked semiconductor layer disposed on the principal surface of the substrate; and (c) a post having an upper surface and a side surface extending in a first direction from the substrate to the stacked semiconductor layer, the post including an upper semiconductor part, a current constriction structure, and a lower semiconductor part having an active layer, the current constriction structure including an oxide portion extending along the side surface of the post, and a semiconductor portion surrounded by the oxide portion. The stacked semiconductor layer is interposed between the substrate and the post. The post includes a peripheral portion extending in the first direction along the side surface of the post, a first portion away from the side surface of the post, the first portion extending in the first direction, a second portion extending in the first direction along the peripheral portion of the post, a third portion disposed between the first portion and the second portion, the third portion extending in the first direction along the first portion, and a fourth portion disposed between the second portion and the third portion, the fourth portion extending in the first direction along the second portion. The oxide portion is located in the second portion and the fourth portion of the post. The semiconductor portion is located in the first portion and the third portion of the post. The post includes a first level part, a second level part, a third level part, and a fourth level part that are sequentially arranged in the first direction. The active layer is located in the first level part, and the current constriction structure is located in the second level part. The peripheral portion includes a first region having a first hydrogen concentration. The first region spans the second level part, the third level part, and the fourth level part. The second level part includes a second region having a second hydrogen concentration. The first hydrogen concentration and the second hydrogen concentration are larger than a hydrogen concentration of the first portion. In addition, the second region has a thickness larger than a thickness of the oxide portion of the current constriction structure.

In accordance with the surface-emitting semiconductor laser, the peripheral portion of the post includes a first region having a first hydrogen concentration higher than the hydrogen concentration of the first portion. The second level part includes a second region having a second hydrogen concentration higher than the hydrogen concentration of the first portion. The high hydrogen concentrations in the first region and the second region are achieved by, for example, an ion injection method with a proton. The first region and the second region have resistivity higher than the first portion of the post because of their high hydrogen concentration. The second region is located on the inner side of the first region in the second level part. The thickness of the second region is larger than the thickness of the oxide portion of the current constriction structure in the second portion. The thick second region guides carrier flow moving toward the semiconductor portion of the current constriction structure in the second level part and the third level part. The shapes of the first region and the second region control the carrier distribution in the active layer. The gain of the fundamental mode and the gain of the higher order mode depend on the carrier distribution in the active layer. For example, the central portion in current spreading contributes to the gain of the fundamental mode, and the portion outside the central portion in current spreading contributes to the gain of the higher order mode.

In a surface-emitting semiconductor laser according to an embodiment, the second portion, the third portion, and the fourth portion may include the second region in the second level part.

In accordance with the surface-emitting semiconductor laser, the second portion, the third portion, and the fourth portion include the second region. This second region defines a current confinement aperture through which carrier flow passes from the fourth level part of the post to the active layer. The first region and the second region have resistivity higher than the first portion of the post because of their high hydrogen concentration. The second region extends from the second portion to the third portion through the fourth portion to enclose the oxide portion of the current constriction structure in the second level part. The second region and the oxide portion form a region having high resistivity. This region having high resistivity guides carrier flow moving toward the semiconductor portion of the current constriction structure in the second level part and the third level part. The shape of the second region in the second portion, the third portion, and the fourth portion controls the carrier distribution in the active layer. The carrier distribution in the active layer is associated with the distribution of the gain in the fundamental mode and the higher order mode.

In a surface-emitting semiconductor laser according to an embodiment, preferably, the second portion includes the second region in the second level part. In addition, the second hydrogen concentration of the second region is larger than the hydrogen concentration of the first portion and a hydrogen concentration of the third portion.

In accordance with the surface-emitting semiconductor laser, the hydrogen concentrations of the first portion and the third portion in the second level part are smaller than the second hydrogen concentration of the second region. The second portion includes the second region, while the third portion does not include the second region. The semiconductor portion and the oxide portion of the current constriction structure define a current confinement aperture through which carrier flow passes from the fourth level part to the active layer. The oxide portion and the second region form a region having high resistivity. This region having high resistivity guides carrier flow moving toward the current confinement aperture in the second level part and the third level part. The carrier distribution in the active layer is defined in accordance with the shapes of the oxide portion and the second region. The carrier distribution in the active layer is associated with the distribution of the gain in the fundamental mode and the higher order mode.

In a surface-emitting semiconductor laser according to an embodiment, preferably, the third level part includes a third region having a third hydrogen concentration higher than the hydrogen concentration of the first portion. The second portion includes the third region. The third region is connected to the second region.

In accordance with the surface-emitting semiconductor laser, the third level part of the post includes the third region having the third hydrogen concentration higher than the hydrogen concentration of the first portion. The high hydrogen concentration in the third region is achieved by, for example, an ion injection method. The second region and the third region have resistivity higher than the first portion of the post because of their high hydrogen concentration. The third level part is located in the third region in the second portion. The third region is connected to the second region located in the second level part to form a region having high resistivity ranging from the second level part to the third level part in the second portion. The region having high resistivity guides carrier flow moving toward the semiconductor portion of the current constriction structure in the third level part and the fourth level part, which are away from the semiconductor portion of the current constriction structure. The shapes of the second region and the third region control the carrier distribution in the active layer. The region having high resistivity may allocate the gain to the fundamental mode and the higher order mode through the control of the carrier distribution in the active layer.

In a surface-emitting semiconductor laser according to an embodiment, preferably, the third region includes an inner end disposed away from an inner end of the second region in a direction from the first portion to the second portion.

In accordance with the surface-emitting semiconductor laser, the level difference between the first region and the third region, the level difference between the third region and the second region, and the level difference along the edge of the second region may define a carrier path.

In a surface-emitting semiconductor laser according to an embodiment, the oxide portion may contain aluminum oxide.

In accordance with the surface-emitting semiconductor laser, aluminum oxide has high electrical insulation.

A surface-emitting semiconductor laser according to an embodiment, may further include an electrode in contact with the upper surface of the post. The electrode has an opening located above the first portion and the third portion.

In accordance with the surface-emitting semiconductor laser, the electrode having the opening provides a carrier not from a substantially central portion of the upper surface of the post but from the peripheral portion of the upper surface of the post. The carrier flows through a path defined by the region(s) having a hydrogen concentration larger than the first concentration.

In a surface-emitting semiconductor laser according to an embodiment, the first hydrogen concentration may be 5×10²⁰ cm⁻³ or less and 1×10¹⁸ cm⁻³ or more.

### DETAILED DESCRIPTION OF EMBODIMENTS

The findings of the present invention can be easily understood by considering the following detailed description with reference to the accompanying drawings illustrated as examples. If possible, the same parts are denoted by the same reference symbols.

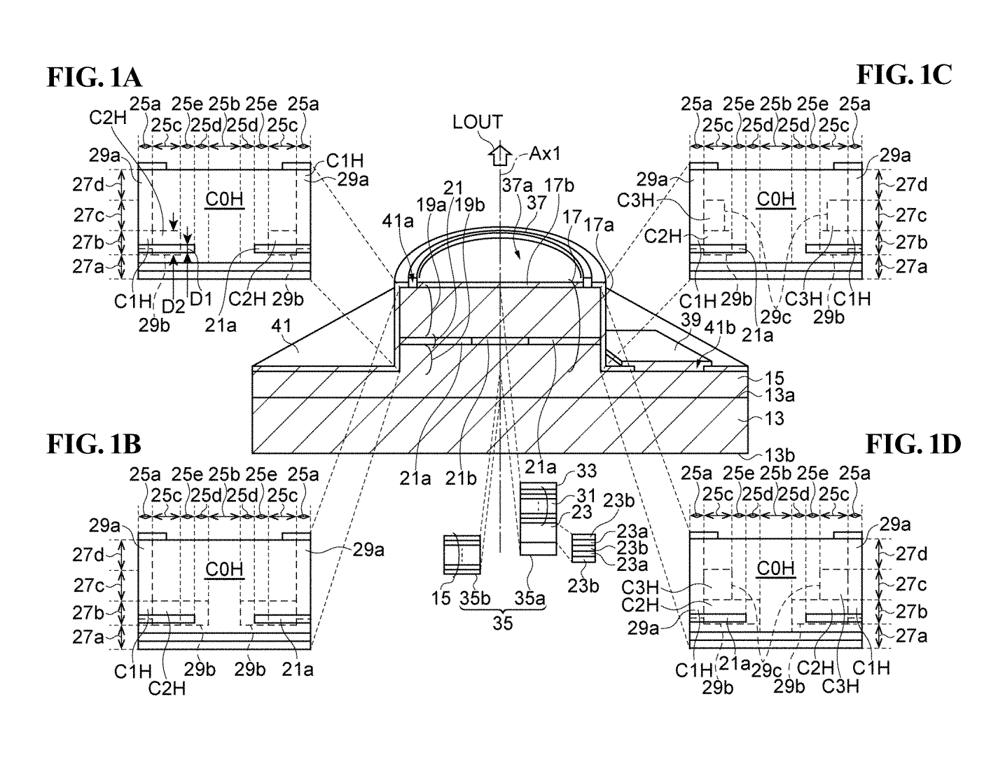

FIGS. 1A to 1D are schematic diagrams illustrating a surface-emitting semiconductor laser according to an embodiment. A surface-emitting semiconductor laser 11 includes a substrate 13, a stacked semiconductor layer 15 for a distributed reflector, and a post 17. The substrate 13 has a principal surface 13a and a rear surface 13b. The stacked semiconductor layer 15 is disposed on the principal surface 13a of the substrate 13. The post 17 has a side surface 17a and an upper surface 17b. The side surface 17a of the post 17 extends in the direction of a first axis Ax1 from the stacked semiconductor layer 15 to the post 17. The upper surface 17b extends in the direction intersecting the direction of the first axis Ax1. The stacked semiconductor layer 15 is interposed between the substrate 13 and the post 17. The post 17 includes an upper semiconductor part 19a and a lower semiconductor part 19b, and a current constriction structure 21. The lower semiconductor part 19b includes an active layer 23. The active layer 23 includes, for example, a quantum well structure having well layers 23a and barrier layers 23b that are stacked alternately. The current constriction structure 21 includes an oxide portion 21a and a semiconductor portion 21b. The oxide portion 21a extends along the side surface 17a of the post 17 and has an opening penetrating therethrough from the upper surface to the lower surface of the oxide portion 21a. The semiconductor portion 21b is filled in this opening of the oxide portion 21a, and the semiconductor portion 21b is surrounded by the oxide portion 21a. The semiconductor portion 21b has a diameter of 5 micrometers or more. The oxide portion 21a contains aluminum oxide. Aluminum oxide has a very large resistivity as compared with that of the semiconductor portion 21b.

The post 17 includes a peripheral portion 25a, a first portion 25b, a second portion 25c, a third portion 25d, and a fourth portion 25e. The peripheral portion 25a, the first portion 25b, the second portion 25c, the third portion 25d, and the fourth portion 25e extend in the direction of the first axis Ax1. The post 17 includes the peripheral portion 25a, the first portion 25b, the second portion 25c, the third portion 25d, and the fourth portion 25e. The peripheral portion 25a is a cylindrical portion that is closed along the side surface 17a of the post 17. The first portion 25b is a columnar portion that is away from the side surface 17a of the post 17 and extends in the direction of the first axis Ax1. The second portion 25c is a closed cylindrical portion that extends in the direction of the first axis Ax1 along the peripheral portion 25a of the post 17. The third portion 25d is a closed cylindrical portion that extends in the direction of the first axis Axl along the second portion 25c and is disposed between the first portion 25b and the second portion 25c. The fourth portion 25e is a closed cylindrical portion that extends in the direction of the first axis Ax1 along the first portion 25b and is disposed between the second portion 25c and the third portion 25d.

The oxide portion 21a is located in the second portion 25c and the fourth portion 25e of the post 17. The semiconductor portion 21b is located in the first portion 25b and the third portion 25d of the post 17. The post 17 includes a first level part 27a, a second level part 27b, a third level part 27c, and a fourth level part 27d. The first level part 27a, the second level part 27b, the third level part 27c, and the fourth level part 27d are sequentially arranged in the direction of the first axis Ax1. The active layer 23 is located in the first level part 27a. The current constriction structure 21 is located in the second level part 27b.

The peripheral portion 25a includes a first region 29a having a first hydrogen concentration C1H. The first region 29a is formed in the second level part 27b, the third level part 27c, and the fourth level part 27d. The second level part 27b includes a second region 29b having a second hydrogen concentration C2H. The first portion 25b has a hydrogen concentration C0H. The second portion 25c includes the second region 29b. The second region 29b is connected to the first region 29a. The first hydrogen concentration C1H and the second hydrogen concentration C2H are higher than the hydrogen concentration C0H of the first portion 25b. The thickness D1 of the oxide portion 21a of the current constriction structure 21 is smaller than the thickness D2 of the second region 29b in the second portion 25c.

In accordance with the surface-emitting semiconductor laser 11, the peripheral portion 25a of the post 17 includes the first region 29a having the first hydrogen concentration C1H higher than the hydrogen concentration C0H of the first portion 25b. The second level part 27b includes the second region 29b having the second hydrogen concentration C2H higher than the hydrogen concentration C0H. The high hydrogen concentrations in the first region 29a and the second region 29b are achieved by, for example, an ion injection method. The first region 29a and the second region 29b have resistivity higher than the first portion 25b of the post 17 because of their high hydrogen concentration. The second region 29b is located on the inner side of the first region 29a in the second portion 25c in the second level part 27b. The thickness D2 of the second region 29b is larger than the thickness D1 of the oxide portion 21a of the current constriction structure 21 in the second portion 25c. The thick second region 29b may guide carrier flow moving toward the semiconductor portion 21b of the current constriction structure 21 in the second level part 27b and the third level part 27c. The shapes of the first region 29a and the second region 29b control the carrier distribution in the active layer 23. The gain of the fundamental mode and the gain of the higher order mode depend on the carrier distribution in the active layer 23. For example, the central portion in the spread current contributes to the gain of the fundamental mode, and the portion outside the spread current contributes to the gain of the higher order mode.

The hydrogen concentration C0H of the first portion 25b is, for example, in the range from 1×10¹⁶ to 7×10¹⁷ cm⁻¹. This hydrogen concentration is the hydrogen concentration that is contained in the semiconductor grown by, for example, the metal-organic vapor phase epitaxy (MOVPE) method and remains grown, or the hydrogen concentration after reduced by a heat treatment applied to this semiconductor.

The first hydrogen concentration C1H of the first region 29a is 5×10²⁰ cm⁻³ or less, which is larger than 1×10¹⁸ cm⁻³. The semiconductor region having this hydrogen concentration is prepared by, for example, ion injection with a proton. The hydrogen concentration profile of the first region 29a has the shape reflecting formation by plural times of ion injection with different accelerating energies and has portions with a significant large hydrogen concentration according to the number of times of ion injection. This provides the profile with high hydrogen concentrations ranging from the second level part 27b to the fourth level part 27d. The second hydrogen concentration C2H of the second region 29b is 5×10²⁰ cm⁻³ or less, which is larger than 1×10¹⁸ cm⁻³. The semiconductor region having this hydrogen concentration has, for example, the shape reflecting formation by single ion injection. In this case, plural times of ion injection may be applied if needed.

As desired, the third level part 27c may include the third region 29c. The third region 29c has a third hydrogen concentration C3H higher than the hydrogen concentration C0H of the first portion 25b. The third hydrogen concentration C3H of the third region 29c is 5×10²⁰ cm⁻³ or less, which is larger than 1×10¹⁸ cm⁻³. The semiconductor region having this hydrogen concentration has, for example, the shape reflecting formation by a single ion injection. In this case, plural times of ion injection may be applied if needed. The second portion 25c includes the third region 29c. The third region 29c is connected to the second region 29b. In the fourth level part 27d, the region from the first portion 25b to the fourth portion 25e does not include a region having high hydrogen concentration. Due to such a region having low hydrogen concentration, the fourth level part 27d allows a carrier to flow in the traverse direction.

In accordance with the surface-emitting semiconductor laser 11, the third level part 27c of the post 17 includes the third region 29c having the third hydrogen concentration C3H higher than the hydrogen concentration C0H of the first portion 25b. The third high hydrogen concentration C3H in the third region 29c is achieved by, for example, an ion injection method with a proton. The second region 29b and the third region 29c have resistivity higher than the first portion 25b of the post 17 because of their high hydrogen concentration. The third region 29c is located in the second portion 25c in the third level part 27c. The third region 29c is connected to the second region 29b located in the second level part 27b to form a region having high resistivity ranging from the second level part 27b to the third level part 27c in the second portion 25c. The region having high resistivity may guide carrier flow moving toward the semiconductor portion 21b of the current constriction structure 21 in the third level part 27c and the fourth level part 27d, which are away from the semiconductor portion 21b of the current constriction structure 21. The shapes of the second region 29b and the third region 29c control the carrier distribution in the active layer 23. The region having high resistivity may allocate the gain to the fundamental mode and the higher order mode through the control of the carrier distribution in the active layer 23.

The upper semiconductor part 19a may include an upper stacked layer 31 and a contact layer 33 disposed on the upper stacked layer 31. The upper stacked layer 31 forms an upper distributed Bragg reflector. The lower semiconductor part 19b includes, in addition to the active layer 23, a first lower stacked layer 35a. The first lower stacked layer 35a is disposed on the second lower stacked layer 35b (this layer corresponds to the stacked semiconductor layer 15 described above) located directly under the post 17. The first lower stacked layer 35a and the second lower stacked layer 35b constitute a lower stacked layer 35, which functions as a lower distributed Bragg reflector.

The surface-emitting semiconductor laser 11 further includes a first electrode 37 in contact with the upper surface 17b of the post 17. The first electrode 37 has an opening 37a located above the first portion 25b and the third portion 25d. The first electrode 37 having the opening 37a provides a carrier not from a substantially central portion of the upper surface 17b of the post 17 but from the peripheral portion of the upper surface 17b of the post 17. The carrier flows through a path defined by the regions having a hydrogen concentration larger than the hydrogen concentration C0H of the first portion 25b. A laser beam LOUT is emitted from the surface-emitting semiconductor laser 11 through the opening 37a.

The surface-emitting semiconductor laser 11 may further include a second electrode 39 in contact with the upper surface of the second lower stacked layer 35b (this layer corresponds to the stacked semiconductor layer 15 described above). The second electrode 39 provides a carrier not from a substantially central portion of the second lower stacked layer 35b directly under the post 17 but from the peripheral portion of the second lower stacked layer 35b. The carrier flows through a path that leads to the first lower stacked layer 35a through the second lower stacked layer 35b.

The surface-emitting semiconductor laser 11 includes a passivation film 41 that covers the side surface 17a and upper surface 17b of the post 17 and the surface of the stacked semiconductor layer 15. The passivation film 41 has a first opening 41a located above the upper surface 17b of the post 17 and a second opening 41b located above the upper surface of the stacked semiconductor layer 15. The passivation film 41 contains, for example, a silicon-based inorganic insulating material.

Example of Surface-Emitting Semiconductor Laser 11
Substrate 13: n-type GaAs substrate
Height of post 17: 4 to 7 micrometers
Diameter of post 17: 15 to 40 micrometers
Current constriction structure 21
Oxide portion 21a: alumina (Al₂O₃)
Semiconductor portion 21b: AlₓGa₁₋ₓAs (x=0.98)
Height of post 17 (distance from upper surface of post 17 to upper surface of oxide portion 21a): 2 to 4 micrometers
Well layer 23a/barrier layer 23b of active layer 23, GaAs/AlGaAs, three quantum wells,
Upper stacked layer 31 that forms upper distributed Bragg reflector: AlₓGa₁₋ₓAs (x=0.12)/Al_{y}Ga_{1-y}As (y=0.90), 23 pairs
Contact layer 33: GaAs
Lower stacked layer 35 that forms lower distributed Bragg reflector: AlₓGa₁₋ₓAs (x=0.12)/Al_{y}Ga_{1-y}As (y=0.90), 35 pairs
First electrode 37 (p-side electrode): Ti/Au
Second electrode 39 (n-side electrode): AuGe/Ni/Au
Passivation film 41: silicon dioxide film
Thickness of first region 29a: 2 to 4 micrometers
Thickness of second region 29b: 0.5 to 3 micrometers
Thickness of third region 29c: 0.5 to 3 micrometers

In the cross section perpendicular to the normal of the principal surface 13a of the substrate 13, the first portion 25b in the post 17 has an outer diameter DI1A so as to be accommodated in a circle of 4 micrometers (in diameter). The first portion 25b is included in a cylinder having the outer diameter DI1A as a bottom diameter.

In the cross section perpendicular to the normal of the principal surface 13a of the substrate 13, the second portion 25c in the post 17 has an outer diameter DI2A so as to be accommodated in a circle of 12 micrometers (in diameter). The second portion 25c is included in a cylinder having the outer diameter DI2A as a bottom diameter.

In the cross section perpendicular to the axis perpendicular to the principal surface 13a of the substrate 13, the third portion 25d in the post 17 has an outer diameter DI3A so as to be accommodated in a circle of 8 micrometers (in diameter). The third portion 25d is included in a cylinder having the outer diameter DI3A as a bottom diameter.

In the cross section perpendicular to the axis perpendicular to the principal surface 13a of the substrate 13, the fourth portion 25e in the post 17 has an outer diameter DI4A so as to be accommodated in a circle of 10 micrometers (in diameter). The fourth portion 25e is included in a cylinder having the outer diameter DI4A as a bottom diameter.

A method for producing the surface-emitting semiconductor laser 11 will be described. Plural semiconductor layers described in an embodiment of the surface-emitting semiconductor laser 11 are grown on an n-type GaAs substrate by using a metal-organic vapor phase epitaxy (MOVPE) method to form an epitaxial substrate.

A first mask for use in a first proton injection process is formed on the principal surface of the epitaxial substrate. The first mask has a pattern for preventing proton injection in a circular region of 15 micrometers (in diameter) from the center of a semiconductor post to be formed.
The first mask has, for example, a patterned resist film.
The proton injection conditions in the first proton injection process for the periphery are described below.
I/I accelerating energy: various energy conditions are used in the range from 200 keV to 370 keV. The dose is 1×10¹⁴ cm⁻². In this process, a high proton concentration region is formed from the surface of the epitaxial substrate to a semiconductor layer for an oxidation constriction layer in the direction perpendicular to the principal surface of the substrate (in the depth direction).
The first mask is removed after the first proton injection process is complete.

A second mask for use in a second proton injection process is formed on the principal surface of the epitaxial substrate. The second mask has a pattern for preventing proton injection in a circular region 10 micrometers in diameter from the center of a semiconductor post to be formed. The second mask has, for example, a patterned resist film. The proton injection conditions in the second proton injection process will be described for each structure. In this process, a high proton concentration region is formed around the semiconductors of the second level part 27b and the third level part 27c away from the surface of the epitaxial substrate in the direction perpendicular to the principal surface of the substrate (in the depth direction).

After the first proton injection process and the second proton injection process, a post is formed by etching the plural semiconductor layers of the epitaxial substrate. As desired, additional mask formation and additional ion injection may be performed. After the post is formed, a current constriction structure for oxidation constriction is formed. This formation is performed by, for example, thermal oxidation using water vapor. The diameter of the semiconductor region of the current constriction structure is 8 micrometers. A silicon dioxide film for forming a passivation film is deposited on the entire surface. An opening for electrical connection is formed in the silicon dioxide (SiO₂) film by photolithography and etching. Subsequently, an anode electrode and a cathode electrode are formed.

### First Embodiment

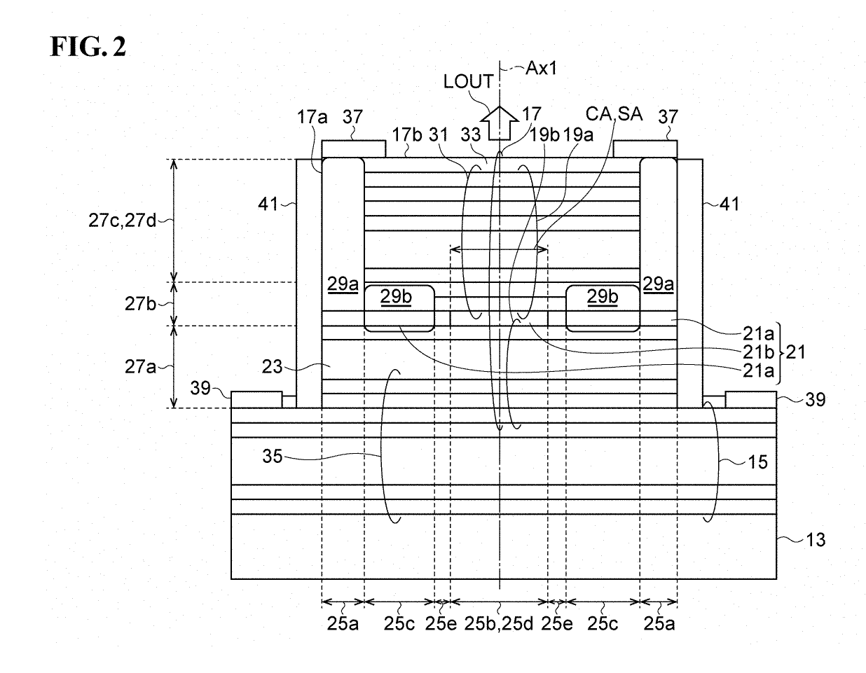

A surface-emitting semiconductor laser 11 includes a first region 29a and a second region 29b each having high resistivity. The region other than the first region 29a and the second region 29b is formed of semiconductors having conductivity better than that of the regions with high resistivity. As illustrated in FIG. 1A and FIG. 2, a second portion 25c includes the second region 29b in a second level part 27b. A first portion 25b, a third portion 25d, and a fourth portion 25e do not include the second region 29b in the second level part 27b. Specifically, the first portion 25b, the second portion 25c, the third portion 25d, and the fourth portion 25e do not include a region with high resistivity in the level parts above the second level part 27b. The second hydrogen concentration C2H of the second region 29b is larger than the hydrogen concentrations of the first portion 25b, the third portion 25d, and the fourth portion 25e. In a peripheral portion 25a, the first region 29a is disposed from the second level part 27b to an upper surface 17b of a post 17. The second region 29b is connected to the first region 29a in the second level part 27b. Since the first portion 25b and the third portion 25d in the second level part 27b do not include a region with high resistivity, a current constriction structure 21 defines a current confinement aperture.

In accordance with the surface-emitting semiconductor laser 11, the hydrogen concentrations of the first portion 25b and the third portion 25d in the second level part 27b are smaller than the second hydrogen concentration C2H of the second region 29b. The second portion 25c includes the second region 29b. The second portion 25c and the third portion 25d do not include the second region 29b. The semiconductor portion 21b of the current constriction structure 21 defines a current confinement aperture through which carrier flow is to pass from the fourth level part 27d to the active layer 23. An oxide portion 21a of the current constriction structure 21 and the second region 29b form a region having high resistivity. This region having high resistivity may guide carrier flow moving toward the current confinement aperture in the second level part 27b and the third level part 27c. The oxide portion 21a of the current constriction structure 21 and the second region 29b control the carrier distribution in the active layer 23. The carrier distribution in the active layer 23 is associated with the distribution of the gain in the fundamental mode and the higher order mode. The proton injection conditions in the second proton injection process for injecting hydrogen into the second level part 27b are described below. An accelerating energy condition of 370 keV is used. The dose is 1×10¹⁴ cm⁻². In the first embodiment, the proton injection in the second proton injection process is performed on the peripheral portion 25a, the second portion 25c, and the fourth portion 25e.

In accordance with this structure, the carrier flow from a first electrode 37 is guided by the first region 29a in the fourth level part 27d and the third level part 27c. The carrier flow from the first electrode 37 is guided by the second region 29b in the third level part 27c and the second level part 27b. Subsequently, these carrier flows move into the semiconductor portion 21b of the current constriction structure 21. The first region 29a and the second region 29b that are formed by proton injection cause the carrier flow from the electrode on the post to be confined to the traverse direction. The proton-injected regions allow carrier constriction in the first stage. The constricted carrier flow reaches the current constriction structure 21, where the carrier flow is also constricted. The previously shaped carrier flow reaches the current constriction structure 21, and the carrier concentration is relaxed around the current constriction structure 21. Relaxing the carrier concentration allows the distribution of the carrier injected into the active layer 23 to be shaped so as to largely overlap with that of the fundamental transverse mode. As a result, this shaped carrier distribution suppresses the higher order traverse mode. Suppressing the higher order mode may narrow the spectral line width. The diameter CA of the current confinement aperture and the outer diameter SA of the semiconductor portion 21b are, for example, 8 micrometers.

### Second Embodiment

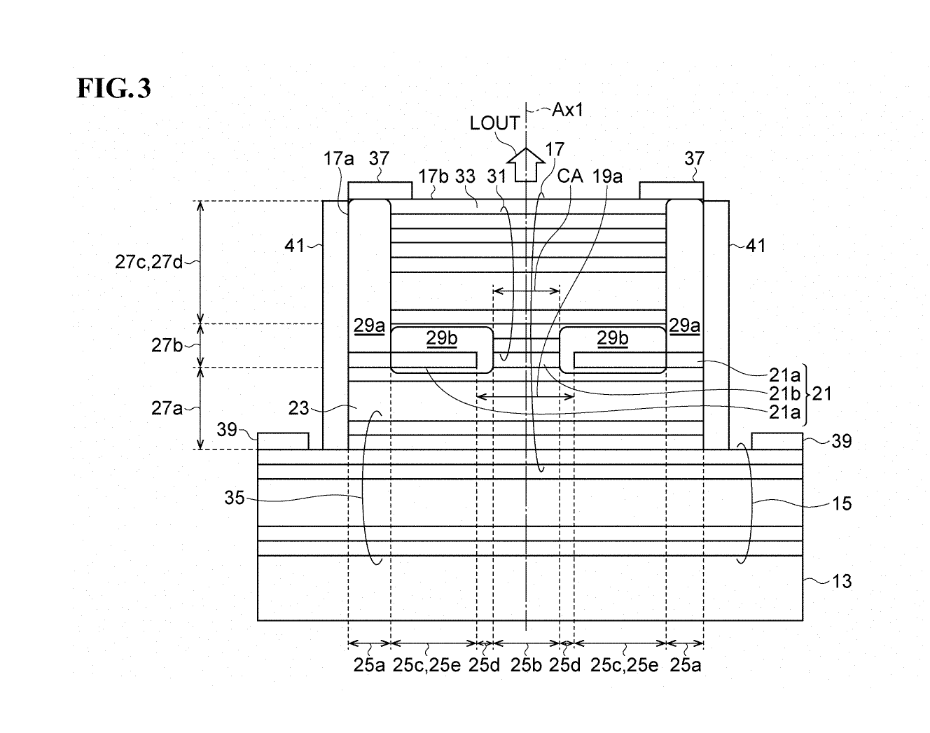

A surface-emitting semiconductor laser 11 includes a first region 29a and a second region 29b each having high resistivity. The region other than the first region 29a and the second region 29b is formed of semiconductors having conductivity better than that of the regions with high resistivity. As illustrated in FIG. 1A and FIG. 3, a second portion 25c, a third portion 25d, and a fourth portion 25e include the second region 29b in a second level part 27b. A first portion 25b does not include the second region 29b in the second level part 27b. Specifically, the first portion 25b, the second portion 25c, the third portion 25d, and the fourth portion 25e do not include a region with high resistivity in the level parts above the second level part 27b. The second hydrogen concentration C2H of the second region 29b is higher than the hydrogen concentration C0H of the first portion 25b. In a peripheral portion 25a, the first region 29a is disposed from the second level part 27b to an upper surface 17b of a post 17. The second region 29b is connected to the first region 29a in the second level part 27b. The first portion 25b in the second level part 27b does not include a region with high resistivity.

In accordance with the surface-emitting semiconductor laser 11, the second region 29b is disposed in the second portion 25c, the third portion 25d, and the fourth portion 25e. This second region 29b defines a current confinement aperture through which carrier flow is to pass from the fourth level part 27d of the post 17 to the active layer 23. The first region 29a and the second region 29b have resistivity higher than the first portion 25b of the post 17 because of their high hydrogen concentration. The second region 29b extends from the second portion 25c to the third portion 25d through the fourth portion 25e to enclose an oxide portion 21a of a current constriction structure 21 in the second level part 27b. The second region 29b and the oxide portion 21a form a region having high resistivity. This region having high resistivity may guide carrier flow moving toward the semiconductor portion 21b of the current constriction structure 21 in the second level part 27b and the third level part 27c. The shape of the second region 29b in the second portion 25c, the third portion 25d, and the fourth portion 25e controls the carrier distribution in the active layer 23. The carrier distribution in the active layer 23 is associated with the distribution of the gain in the fundamental mode and the higher order mode. The conditions of the second proton injection process for injecting hydrogen into the second level part 27b are described below. An accelerating energy condition of 370 keV is used. The dose is 1×10¹⁴ cm⁻². In this embodiment, the proton injection in the second proton injection process is performed on the peripheral portion 25a, the second portion 25c, the third portion 25d, and the fourth portion 25e.

In accordance with this structure, the carrier flow from a first electrode 37 is guided by the first region 29a in the fourth level part 27d and the third level part 27c. This carrier flow is guided by the second region 29b in the third level part 27c and the second level part 27b. This carrier flow moves into the current confinement aperture in the second level part 27b. The current confinement aperture is defined by the second region 29b that encloses the oxide portion 21a. By this double constriction structure, both of high electrical insulation of the oxide portion 21a and high precision of the shape of the second region 29b is realized. The first region 29a and the second region 29b that are formed by proton injection cause the carrier flow from the first electrode 37 on the post 17. As a result, the carrier flow is confined to the traverse direction. The proton-injected regions allow carrier constriction in the first stage. The constricted carrier flow reaches the second level part 27b, where the carrier flow is also constricted. The shaped carrier flow reaches the second level part 27b, and carrier concentration is relaxed around the current constriction structure 21. Relaxing the carrier concentration allows the distribution of the carrier injected into the active layer 23 to be shaped so as to largely overlap with that of the fundamental transverse mode. This shaping suppresses the higher order transverse mode. Suppressing the higher order mode may narrow the spectral line width.

The diameter CA of the current confinement aperture is 6 micrometers, and the outer diameter SA of the semiconductor portion 21b is 8 micrometers, for example. The current confinement is performed by the second region 29b to which proton injection has imparted high resistivity. The current constriction structure 21 is used not for current confinement but to provide a change in light refractive index and control the transverse mode. The transverse mode control by the current distribution and the transverse mode control by the refractive index distribution may be performed independently. These transverse mode controls may change the spectral width.

### Third Embodiment

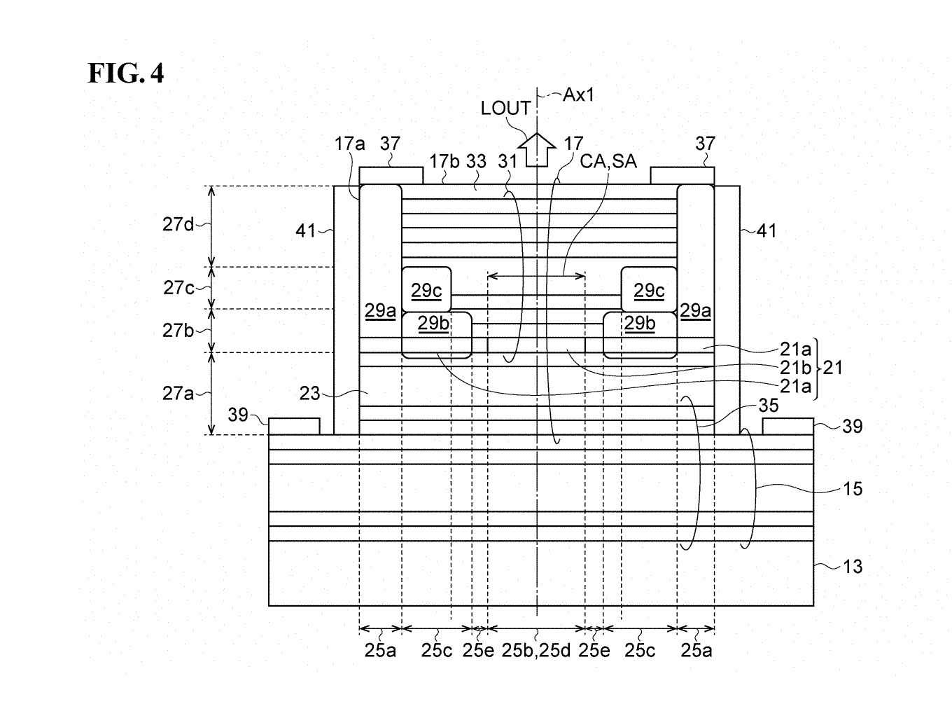

A surface-emitting semiconductor laser 11 includes a first region 29a, a second region 29b, and a third region 29c each having high resistivity. The region other than these regions is formed of semiconductors having conductivity better than those of the regions with high resistivity. As illustrated in FIG. 1A and FIG. 4, a second portion 25c includes the second region 29b in a second level part 27b. The second portion 25c includes the third region 29c in the third level part 27c. The third region 29c is connected to the second region 29b. The inner end of the third region 29c is disposed away from the inner end of the second region 29b in the direction from a first portion 25b to the second portion 25c. The first portion 25b, a third portion 25d, and a fourth portion 25e do not include the second region 29b and the third region 29c in the second level part 27b and the third level part 27c. The level difference between the first region 29a and the third region 29c, the level difference between the third region 29c and the second region 29b, and the upper edge of the second region 29b may define a carrier flow path. Specifically, the first portion 25b, the second portion 25c, the third portion 25d, and the fourth portion 25e do not include a region with high resistivity in the level part on the third level part 27c. The second hydrogen concentration C2H of the second region 29b and the third hydrogen concentration C3H of the third region 29c are larger than the hydrogen concentration C0H of the first portion 25b, the third portion 25d, and the fourth portion 25e. In a peripheral portion 25a, the first region 29a is disposed from the second level part 27b to an upper surface 17b of a post 17. The second region 29b is connected to the first region 29a in the second level part 27b. The third region 29c is connected to the first region 29a in the third level part 27c. The first portion 25b and the third portion 25d in the second level part 27b that defines the current confinement aperture do not include a region with high resistivity.

In accordance with the surface-emitting semiconductor laser, the third level part 27c of the post 17 includes the third region 29c. The third region 29c has the third hydrogen concentration C3H higher than the hydrogen concentration C0H of the first portion 25b. The high hydrogen concentration of the third region 29c in the third level part 27c is achieved by, for example, an ion injection method with a proton. The second region 29b and the third region 29c have resistivity higher than the first portion 25b of the post because of their high hydrogen concentration. The third region 29c is located in the second portion 25c in the third level part 27c. The third region 29c is connected to the second region 29b located in the second level part 27b. Thus, a region having high resistivity ranging from the second level part 27b to the third level part 27c is formed in the second portion 25c. The region having high resistivity may guide carrier flow moving toward the semiconductor portion 21b of a current constriction structure 21 in the third level part 27c and the fourth level part 27d, which are away from the semiconductor portion 21b of the current constriction structure 21. The shapes of the second region 29b and the third region 29c control the carrier distribution in the active layer 23. The region having high resistivity may allocate the gain to the fundamental mode and the higher order mode through the control of the carrier distribution in the active layer 23. The conditions of the second proton injection process for injecting hydrogen into the second level part 27b are described below. An accelerating energy condition of 370 keV is used. The dose is 1×10¹⁴cm⁻². In this embodiment, the proton injection in the second proton injection process is performed on the entire peripheral portion 25a and the entire second portion 25c. The conditions of the third proton injection process for injecting hydrogen into the third level part 27c are described below. An energy condition of 300 keV is used. The dose is 1×10¹⁴ cm⁻². In this embodiment, the proton injection in the third proton injection process is performed on the peripheral portion 25a and the peripheral portion in the second portion 25c. The pattern of a mask used in the second proton injection process and the pattern of a mask used in the third proton injection process are defined such that the inner end of the third region 29c is disposed away from the inner end of the second region 29b in the direction from the first portion 25b to the second portion 25c.

In accordance with this structure, the carrier flow from a first electrode 37 is guided by the first region 29a in the fourth level part 27d and the third level part 27c. This carrier flow is guided by the second region 29b in the third level part 27c and the second level part 27b. Subsequently, these carrier flows move into the semiconductor portion 21b of the current constriction structure 21. The first region 29a and the second region 29b that are formed by proton injection cause the carrier flow from the electrode on the post 17. As a result, the carrier flow is confined to the traverse direction. The proton-injected regions allow carrier constriction in the first stage. The constricted carrier flow reaches the current constriction structure 21, where the carrier flow is also constricted. The shaped carrier flow reaches the current constriction structure 21, and the carrier concentration is relaxed around the current constriction structure 21. Relaxing the carrier concentration allows the distribution of the carrier injected into the active layer to be shaped so as to largely overlap with that of the fundamental transverse mode. This shaping suppresses generation of the higher order transverse mode. Suppressing the higher order mode may narrow the spectral line width. In an area between the current constriction structure 21 and the first electrode 37, the regions with high resistivity have two level differences. These level differences may reduce carrier concentration in the current confinement aperture in the current constriction structure 21. The inner diameter of the third region 29c is 10 micrometers, and the outer diameter is 12 micrometers, for example.

### Fourth Embodiment

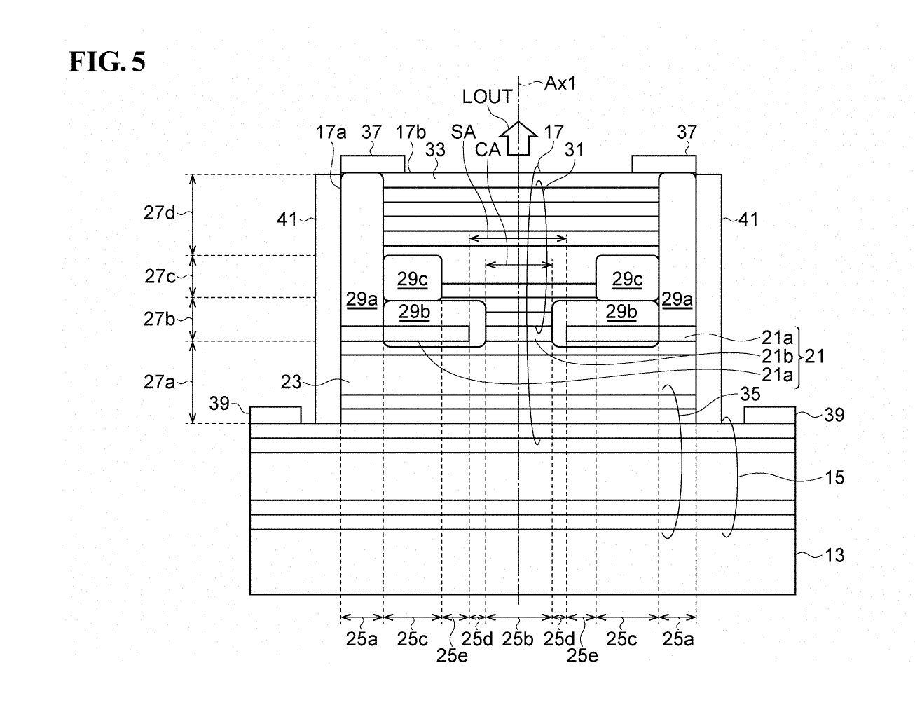

A surface-emitting semiconductor laser 11 includes a first region 29a, a second region 29b, and a third region 29c each having high resistivity. The region other than these regions is formed of semiconductors having conductivity better than those of the regions with high resistivity. As illustrated in FIG. 1A and FIG. 5, a second portion 25c, a third portion 25d, and a fourth portion 25e include the second region 29b in a second level part 27b. The second portion 25c includes the third region 29c in the third level part 27c. A first portion 25b does not include the second region 29b and the third region 29c in the second level part 27b and the third level part 27c. Specifically, the first portion 25b, the second portion 25c, the third portion 25d, and the fourth portion 25e do not include a region with high resistivity in the level part on the third level part 27c. The second hydrogen concentration C2H of the second region 29b and the third hydrogen concentration C3H of the third region 29c are larger than the hydrogen concentration C0H of the first portion 25b. In a peripheral portion 25a, the first region 29a is disposed from the second level part 27b to an upper surface 17b of a post 17. The second region 29b is connected to the first region 29a in the second level part 27b. The third region 29c is connected to the first region 29a in the third level part 27c. The first portion 25b in the second level part 27b does not include a region with high resistivity.

In accordance with the surface-emitting semiconductor laser 11, the post 17 includes the second region 29b in the second level part 27b and includes the third region 29c in the third level part 27c. The second region 29b and the third region 29c respectively have the second hydrogen concentration C2H and the third hydrogen concentration C3H. The second hydrogen concentration C2H and the third hydrogen concentration C3H are higher than the hydrogen concentration C0H of the first portion 25b. The high hydrogen concentrations of the second region 29b in the second level part 27b and the third region 29c in the third level part 27c are achieved by, for example, an ion injection method with a proton. The second region 29b and the third region 29c have resistivity higher than the first portion 25b of the post because of their high hydrogen concentration. The third region 29c is located in the second portion 25c in the third level part 27c. The third region 29c is connected to the second region 29b located in the second level part 27b to form a region having high resistivity ranging from the second level part 27b to the third level part 27c in the second portion 25c. The second region 29b extends from the second portion 25c to the third portion 25d through the fourth portion 25e to enclose an oxide portion 21a of a current constriction structure 21 in the second level part 27b. The second region 29b and the oxide portion 21a form a region having high resistivity. The region having high resistivity may guide carrier flow moving toward the semiconductor portion 21b of the current constriction structure 21 in the third level part 27c and the fourth level part 27d, which are away from the semiconductor portion 21b of the current constriction structure 21. The shapes of the second region 29b and the third region 29c control the carrier distribution in the active layer 23. The region having high resistivity may allocate the gain to the fundamental mode and the higher order mode through the control of the carrier distribution in the active layer 23. The proton injection conditions in the second proton injection process for injecting hydrogen into the second level part 27b are described below. An accelerating energy condition of 370 keV is used. The dose is 1×10¹⁴ cm⁻². In this embodiment, the proton injection in the second proton injection process is performed on the entire peripheral portion 25a and the entire second portion 25c. The proton injection conditions in the third proton injection process for injecting hydrogen into the third level part 27c are described below. An accelerating energy condition of 300 keV is used. The dose is 1×10¹⁴ cm⁻². In this embodiment, the proton injection in the third proton injection process is performed on the peripheral portion 25a and the peripheral portion in the second portion 25c. The pattern of a mask used in the second proton injection process and the pattern of a mask used in the third proton injection process are defined such that the inner end of the third region 29c is disposed away from the inner end of the second region 29b in the direction from the first portion 25b to the second portion 25c.

In accordance with this structure, the carrier flow from a first electrode 37 is guided by the first region 29a in the fourth level part 27d and the third level part 27c. This carrier flow is guided by the second region 29b in the third level part 27c and the second level part 27b. Subsequently, this carrier flow moves into the current confinement aperture. The first region 29a and the second region 29b that are formed by proton injection cause the carrier flow from the electrode on the post. As a result, the carrier flow is confined to the traverse direction. The proton-injected regions allow carrier constriction in the first stage. The constricted carrier flow reaches the current confinement aperture, where the carrier flow is also constricted. The current confinement aperture is defined by the second region 29b that encloses the oxide portion 21a. By this double constriction structure, both of high electrical insulation of the oxide portion 21a and high precision of the shape of the second region 29b is realized. The carrier concentration is relaxed near the current constriction structure 21. Relaxing the carrier concentration allows the distribution of the carrier injected into the active layer 23 to be shaped so as to largely overlap with that of the fundamental transverse mode. This shaping suppresses for the surface-emitting semiconductor laser 11 to operate at higher order transverse mode. Suppressing the higher order mode may narrow the spectral line width. In an area between the current constriction structure 21 and the first electrode 37, the regions with high resistivity have two level differences. These level differences may reduce carrier concentration in the current confinement aperture. The inner diameter of the third region 29c is 10 micrometers, and the outer diameter is 12 micrometers, for example. The diameter CA of the current confinement aperture is 6 micrometers, and the outer diameter SA of the semiconductor portion 21b is 8 micrometers, for example. The current confinement is performed by the second region 29b to which proton injection has imparted high resistivity. The current constriction structure 21 is used not for current confinement but to provide a change in light refractive index and control the transverse mode. The transverse mode control by the current distribution and the transverse mode control by the refractive index distribution are performed independently. These transverse mode controls may change the spectral width. EXPERIMENTAL EXAMPLE

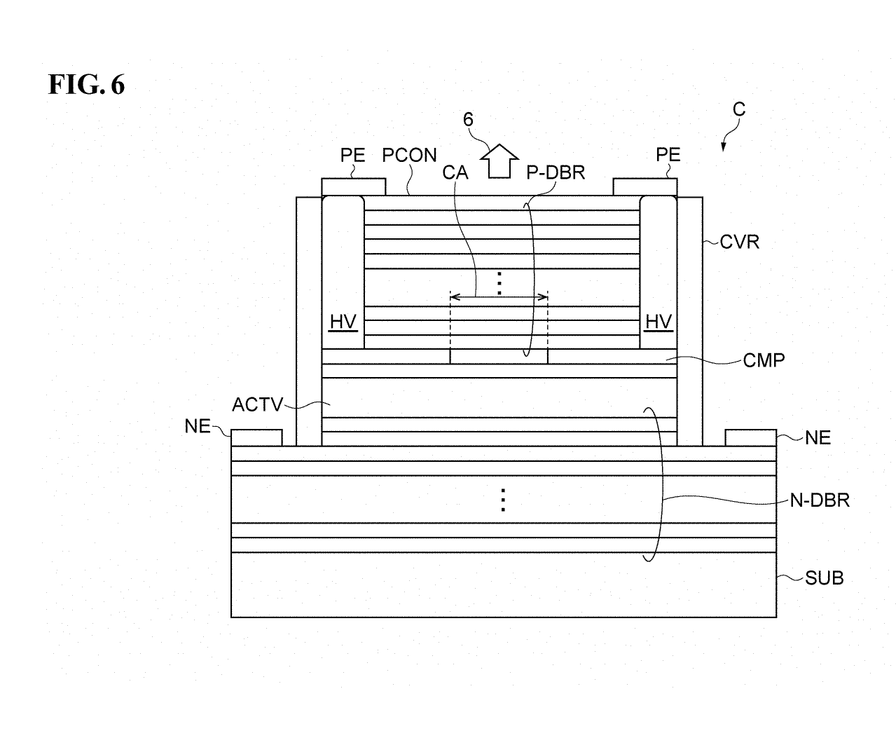

FIG. 6 is a schematic diagram illustrating a surface-emitting semiconductor laser having a region with high resistivity extending along the side surface of a post. The epitaxial structure of the surface-emitting semiconductor laser C in Experimental Example is described.
p-Type contact layer PCON: p-type GaAs
Upper distributed Bragg reflector P-DBR: AlₓGa₁₋ₓAs (x=0.12)/Al_{y}Ga_{1-y}As (y=0.90) 23 pairs
Oxidization constriction structure CMP: AlₓGa₁₋ₓAs (x=0.98), aluminum oxide Active layer ACTV
p-Type spacer layer: AlₓGa₁₋ₓAs (x=0.90)
Undoped spacer layer: AlₓGa₁₋ₓAs (x=0.30)
Quantum well structure: GaAs/AlGaAs, three quantum wells
Undoped spacer layer: AlₓGa₁₋ₓAs (x=0.30)
Lower distributed Bragg reflector N-DBR: AlₓGa₁₋ₓAs (x=0.12)/Al_{y}Ga_{1-y}As (y=0.90) 35 pairs
Substrate: n-type GaAs
Proton injection is performed on the periphery to form a region HV with high resistivity from the upper surface of the post to the constriction structure. The conditions of the proton injection into the periphery are described below.
I/I energy: various energy conditions are used in the range from 200 keV to 370 keV. The dose is 1×10¹⁴ cm⁻². In this process, a high proton concentration region is formed along the side surface of the post from the surface of the epitaxial substrate to a semiconductor layer for an oxidation constriction layer in the direction perpendicular to the principal surface of the substrate (in the depth direction). The surface-emitting semiconductor laser C emits a light 6. The surface from which the light 6 is emitted is the upper surface of the device in the same manner as in the surface-emitting semiconductor laser 11.

Surface-emitting semiconductor lasers were produced by changing the conditions of proton ion injection while the epitaxial structure and the device size of the devices of the embodiments and Experimental Example were the same. The spectral line width of these surface-emitting semiconductor lasers was measured.
Spectral line width in Experimental Example: 0.5 nm
Spectral line width in the first embodiment: 0.3 nm
Spectral line width in the second embodiment: 0.33 nm
Spectral line width in the third embodiment: 0.4 nm
Spectral line width in the fourth embodiment: 0.4 nm
The structures in the first embodiment to the fourth embodiment are different from that in Experimental Example in that the structures include the second region 29b and further the third region 29c in addition to the first region 29a. The spectral line width of the device structures in the first embodiment to the fourth embodiment is narrower than that in Experimental Example. The term “spectral line width” as used herein refers to the full width at half maximum when plural lines of the spectrum distribution attributed to plural transverse modes are fitted by the gauss function.

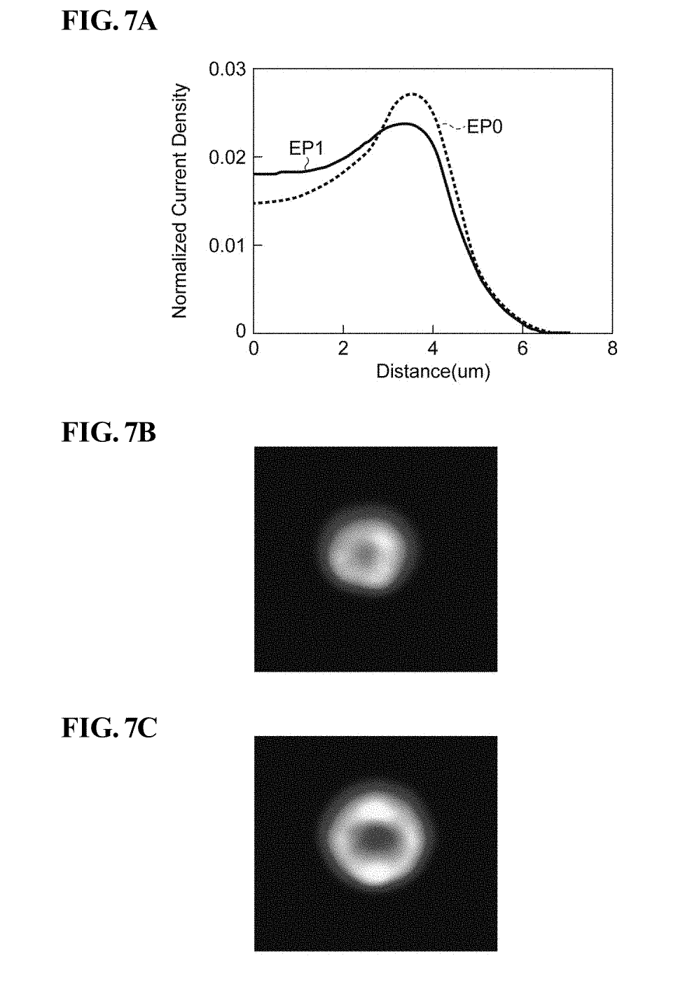

FIG. 7A is a graph showing the calculated values of the current distribution in the structures of the first embodiment and Experimental Example. FIGS. 7B and 7C are views showing the measured results of light emission patterns for the first embodiment and Experimental Example. In the graph of FIG. 7A, the horizontal axis represents the distance from the center of the post. The vertical axis represents the normalized current density. As illustrated in FIG. 7A, the current distribution EP1 of the device structure of the first embodiment and the current distribution EP0 of the device structure of Experimental Example have a minimum value in a central part of the post and a maximum value in a part outside the central part. The difference between the minimum value and the maximum value in the current distribution of the device structure of the first embodiment is larger than the difference between the minimum value and the maximum value in the current distribution of the device structure of Experimental Example. This difference indicates that the device structure of Experimental Example is a structure in which the current concentration occurs in the central part of the post. FIGS. 7B and 7C respectively illustrate the light emission patterns in the first embodiment and Experimental Example. The difference between these light emission patterns supports the difference in the current distribution illustrated in FIG. 7A.

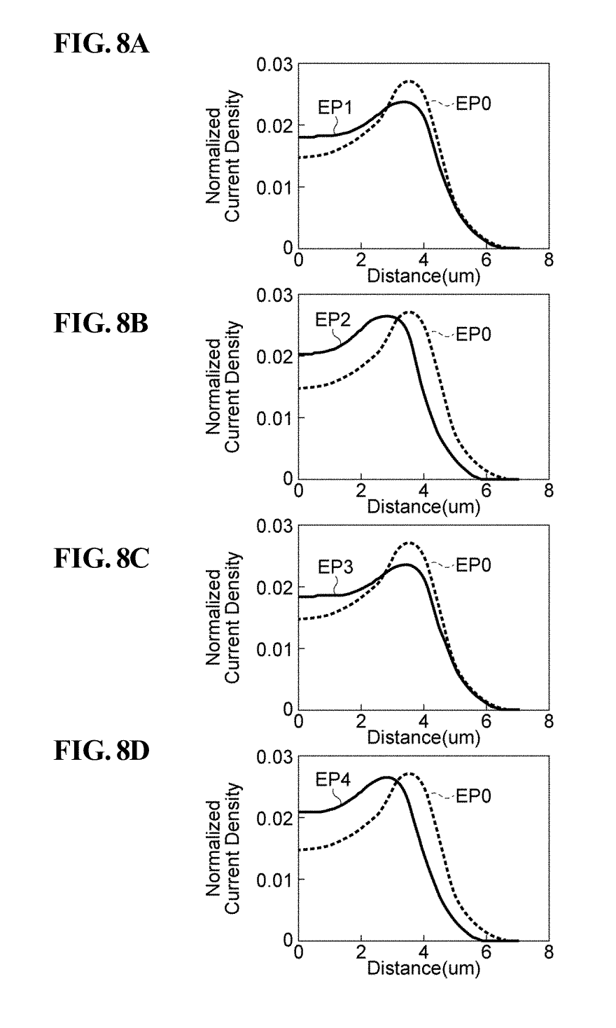

FIGS. 8A to 8D are graphs showing the calculated values of the current distribution in the device structures according to the first embodiment to the fourth embodiment. FIGS. 8A, 8B, 8C, and 8D respectively illustrate the calculated values in the first, second, third and fourth embodiments as well as the calculated value in Experimental Example. FIGS. 8A to 8D indicate that the difference in the shape and location of the regions with high resistivity generates the position of the maximum value in the current distribution and a difference between the maximum value and the minimum value. The difference between the maximum value and the minimum value affects lasing characteristics such as spectral line width that is an indicator of the gain given to the fundamental mode. The beam width in the higher order mode is broader than that in the fundamental mode. The current distribution broadening in FIGS. 8A to 8D is an indicator of the gain given to the higher order mode. This large distribution broadening relatively strengthens the higher order mode compared with the fundamental mode and results in a broad spectral line width.

Although the principles of the present invention are described with reference to the drawings in preferred embodiments, it should be understood by those skilled in the art that arrangements and detail modifications of the present invention can be made without departing from such principles of the present invention. The present invention is not limited to particular structures disclosed in this embodiment. Therefore, all modifications and changes in the scope of the claims and the scope of the spirit are claimed.

1. A surface-emitting semiconductor laser comprising:
a substrate having a principal surface;
a stacked semiconductor layer disposed on the principal surface of the substrate; and
a post having an upper surface and a side surface, the side surface extending along an axis in a first direction from the substrate to the stacked semiconductor layer, the post including an upper semiconductor part, a current constriction structure, and a lower semiconductor part having an active layer, the current constriction structure including an oxide portion extending along the side surface of the post, and a semiconductor portion surrounded by the oxide portion, wherein
the stacked semiconductor layer is interposed between the substrate and the post,
the post includes a peripheral portion extending in the first direction along the side surface of the post, a first portion away from the side surface of the post, the first portion extending in the first direction, a second portion extending in the first direction along the peripheral portion of the post, a third portion disposed between the first portion and the second portion, the third portion extending in the first direction along the first portion, and a fourth portion disposed between the second portion and the third portion, the fourth portion extending in the first direction along the second portion,
the oxide portion is located in the second portion and the fourth portion of the post,
the semiconductor portion is located in the first portion and the third portion of the post,
the post includes a first level part, a second level part, a third level part, and a fourth level part that are sequentially arranged in the first direction,
the active layer is located in the first level part,
the current constriction structure is located in the second level part,
the peripheral portion includes a first region having a first hydrogen concentration,
the first region spans the second level part, the third level part, and the fourth level part,
in the second level part, the second portion of the post includes a second region having a second hydrogen concentration,
the oxide portion of the current constriction stru ure is provided in the second region at the secorid portion,
the first hydrogen concentration and the second hydrogen concentration are larger than a hydrogen concentration of the first portion, and
the second region has a thickness larger than a thickness of the oxide portion of the current constriction structure.

2. The surface-emitting semiconductor laser according to claim 1, wherein
the second region extends from the second portion to the third portion through the fourth portion in the second level part so as to enclose the oxide portion of the current constriction structure in the third portion, and
the second region has an aperture smaller than that of the oxide portion.

3. The surface-emitting semiconductor laser according to claim 1, wherein the second hydrogen concentration is larger than a hydrogen concentration of the third portion.

4. The surface-emitting semiconductor laser according to claim 1, wherein
the third level part includes a third region having a third hydrogen concentration. higher than the hydrogen concentration of the first portion,
the second portion includes the third region, and
the third region is connected to the second region.

5. The surface-emitting semiconductor laser according to claim 4, wherein the third region includes an inner end disposed away from an inner end of the second region in a second direction from the first portion to the second portion.

6. The surface-emitting semiconductor laser according to claim 1, wherein the oxide portion contains aluminum oxide.

7. The surface-emitting semiconductor laser according to claim 1, further comprising an electrode in contact with the upper surface of the post,
wherein the electrode has an opening located above the first portion and the third portion.

8. The surface-emitting semiconductor laser according to claim 1, wherein the first hydrogen concentration is 5×10²⁰ cm⁻³ or less and 1×10¹⁸ cm⁻³ or more,

9. The surface-emitting semiconductor laser according to claim 2, wherein
the third level part includes a third region having a third hydrogen concentration higher than the hydrogen concentration of the first portion,
the second portion includes a third region, and
the third region is connected to the second region.
